(19) United States
(12) Patent Application Publication
(10) Pub. No.: US 2026/0291538 A1
(43) Pub. Date: Sep. 24, 2026

(54) FEEDBACK RECEIVE PATH ISOLATION

(71) Applicant: QUALCOMM Incorporated, San Diego, CA (US)

(72) Inventor: Rahul KARMAKER, San Diego, CA (US)

(21) Appl. No.: 19/088,684

(22) Filed: Mar. 24, 2025

(51) Int. Cl. H04B 1/40; H03F 3/24

(52) U.S. Cl. CPC H04B 1/40; H03F 3/245; H03F 2200/451

(57) ABSTRACT

Certain aspects of the present disclosure provide techniques for feedback receive path isolation. An example transceiver includes a feedback receive path comprising an input node; a reference node; a first variable attenuator; a second variable attenuator; and a pseudo-differential circuit having differential input ports, wherein the first variable attenuator is coupled between the input node and a first input port of the differential input ports, and wherein the second variable attenuator is coupled between the reference node and a second input port of the differential input ports.

### INTRODUCTION

### Field of the Disclosure

Aspects of the present disclosure relate to radio frequency circuitry, and more particularly, to feedback receive path isolation.

### Description of Related Art

Wireless communications systems are widely deployed to provide various telecommunication services such as telephony, video, data, messaging, broadcasts, etc. These wireless communications systems may employ multiple-access technologies capable of supporting communications with multiple users by sharing available wireless communications system resources with those users. Wireless communication devices may communicate radio frequency (RF) signals via any of various suitable radio access technologies (RATs) including, but not limited to, 5G New Radio (NR), Evolved Universal Terrestrial Radio Access (E-UTRA), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., Institute of Electrical and Electronics Engineers (IEEE) 802.11 specifications), any future RAT, and/or the like.

In certain cases, a wireless communications device is equipped with a RF transceiver (also referred to as an RF front-end) for communicating RF signals. In general, a baseband signal is modulated to convey information using a modulation technique, such as phase-shift keying (PSK) or any other suitable modulation technique. In a transmit mode, the RF transceiver is responsible for multiplexing the baseband signal with an RF carrier signal that is transmitted over the air (e.g., a wireless communication channel). Such an operation is called upconversion. In a receive mode, the RF transceiver converts a received RF signal to the baseband signal. Such an operation is called downconversion. The received baseband signal then can be demodulated into the information encoded at a transmitter. The RF transceiver may include a cascade of components in a transmit chain and a receive chain, respectively. The cascade of components may include, for example, one or more of attenuators, switches, couplers, filters, mixers, amplifiers, frequency synthesizers, oscillators, antenna tuners, duplexers, diplexers, detectors, etc.

Although there have been great technological advancements in RF circuitry over many years, challenges still exist. For example, RF circuitry can still encounter crosstalk between certain components. Accordingly, there is a continuous desire to improve the technical performance of RF circuitry, such as crosstalk isolation and/or suppression.

### SUMMARY

Certain aspects provide a transceiver. The transceiver includes a feedback receive path comprising an input node; a reference node; a first variable attenuator; a second variable attenuator; and a pseudo-differential circuit having differential input ports, wherein the first variable attenuator is coupled between the input node and a first input port of the differential input ports, and wherein the second variable attenuator is coupled between the reference node and a second input port of the differential input ports.

Certain aspects provide a method for operating a transceiver. The method includes outputting a signal via a transmit path. The method also includes feeding the signal to an input node of a feedback receive path comprising a reference node; a first variable attenuator; a second variable attenuator; and a pseudo-differential circuit having differential input ports, wherein the first variable attenuator is coupled between the input node and a first input port of the differential input ports, and wherein the second variable attenuator is coupled between the reference node and a second input port of the differential input ports.

Other aspects provide: an apparatus operable, configured, or otherwise adapted to perform any one or more of the aforementioned methods and/or those described elsewhere herein; a non-transitory, computer-readable medium comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 depicts an example wireless communications system.

FIG. 2 depicts an example wireless communications device communicating with another device.

FIG. 3 depicts an example architecture of feedback receive path isolation circuitry.

FIG. 4 depicts another example architecture of feedback receive path isolation circuitry.

FIG. 5 depicts an example transceiver including a transmit path coupled to a feedback receive path that includes isolation circuitry of FIG. 3.

FIG. 6 depicts an example method for wireless communications by an apparatus.

FIG. 7 depicts a communications device that may include various components configured to perform operations for the techniques disclosed herein.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Aspects of the present disclosure provide apparatuses, methods, processing systems, and computer-readable mediums for feedback receive path isolation.

Certain wireless communication devices (e.g., cellular phones, smartphones, or the like) may employ a transceiver to transmit and receive radio frequency (RF) signals. In certain cases, a transmit path of the transceiver may be coupled to a feedback receive path for calibration of the transmit path (such as digital pre-distortion, residual sideband calibration, or the like) and/or monitoring the performance of the transmit path. As an example, a power amplifier (PA) of the transmit path may feed an RF signal to the feedback receive path via an RF coupler, which may be coupled between the output of the PA and the feedback receive path. The feedback receive path may downconvert and filter the RF signal to a baseband signal, and the feedback receive path may feed the baseband signal to an analog-to-digital converter (ADC) for digital processing, such as transmit path calibration and/or monitoring.

Technical problems for RF circuitry include, for example, effective isolation between the transmit path and feedback receive path of the transceiver. In certain cases, the transmit path and the feedback receive path may be coupled to the same power supply and ground nodes used across the transceiver. Due to the common power supply and ground node connections, the transmit path can become conductively coupled to the feedback receive path independent of the RF coupler. For example, crosstalk may be encountered between a driver amplifier (DA) output of the transmit path and a low noise amplifier of the feedback receive path due to conductive coupling between the common power supplies and/or ground nodes. Accordingly, a non-trivial amount of crosstalk between the transmit path and the feedback receive path may affect the signal quality of the signal fed to the feedback receive path via the transmit path.

Certain aspects described herein may overcome the aforementioned technical problem(s), for example, by providing certain feedback receive path isolation circuitry that may enable crosstalk isolation or suppression, for example, between a transmit path and feedback receive path of a transceiver. The feedback receive path isolation circuitry may be included in an input stage of a feedback receive path. The feedback receive path may include a pseudo-differential circuit and variable attenuators symmetrically arranged with respect to differential input ports of the pseudo-differential circuit. As an example, a first variable attenuator may be coupled to a first input port of the differential input ports, and a second variable attenuator may be coupled to a second input port of the differential input ports. The variable attenuators may enable balanced attenuation between the differential input ports of the pseudo-differential circuit, which may in turn suppress or prevent crosstalk from affecting a signal fed to the pseudo-differential circuit.

Certain techniques for feedback receive path isolation described herein may provide various beneficial technical effects and/or advantages. The techniques for feedback receive path isolation may enable improved signal quality associated with signals fed to a feedback receive path. The improved signal quality may be attributable to balanced attenuation applied to differential input ports of a pseudo-differential circuit via the variable attenuators. In certain cases, the balanced attenuation may suppress or prevent certain crosstalk derived from common power supplies and/or ground nodes. In certain cases, the variable attenuators may enable the improved signal quality across a wide frequency bandwidth using single-ended and/or passive circuitry. Accordingly, the variable attenuators may enable the improved signal quality without impacting power consumption, circuit complexity, and/or frequency bandwidth specifications.

### Example Wireless Communications System

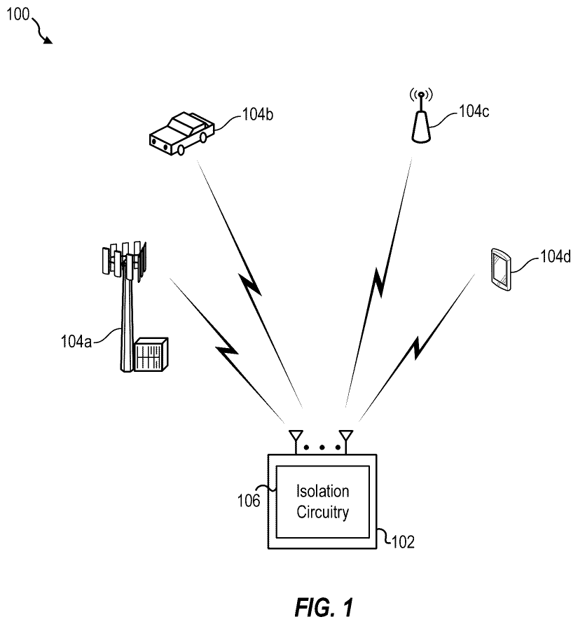

FIG. 1 illustrates an example wireless communications system 100 in which aspects of the present disclosure may be performed. For example, the wireless communications system 100 may include a wireless wide area network (WWAN) and/or a wireless local area network (WLAN). A WWAN may include a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation (2G) or Third Generation (3G) network), a code division multiple access (CDMA) system (e.g., a 2G/3G network), any future WWAN system, or any combination thereof. A WLAN may include a wireless network configured for communications according to an Institute of Electrical and Electronics Engineers (IEEE) standard such as one or more of the 802.11 standards, etc. In some cases, the wireless communications system 100 may include a device-to-device (D2D) communications network or a short-range communications system, such as Bluetooth communications or near field communications (NFC).

As illustrated in FIG. 1, the wireless communications system 100 may include a first wireless device 102 communicating with any of various second wireless devices 104a-d (hereinafter “the second wireless device 104”) via any of various radio access technologies (RATs), where a wireless device may refer to a wireless communications device. The RATs may include, for example, WWAN communications (e.g., E-UTRA and/or 5G NR), WLAN communications (e.g., IEEE 802.11), vehicle-to-everything (V2X) communications, non-terrestrial network (NTN) communications, short-range communications (e.g., Bluetooth), D2D communications, etc.

The first wireless device 102 may include any of various wireless communications devices including a user equipment (UE), a base station, a wireless station, an access point, customer-premises equipment (CPE), etc. In certain aspects, the first wireless device 102 includes isolation circuitry 106 that may enable crosstalk isolation or suppression associated with an input stage of a feedback receive path, in accordance with aspects of the present disclosure.

The second wireless device 104 may include, for example, a base station 104a, a vehicle 104b, an access point (AP) 104c, and/or a UE 104d. Further, the wireless communications systems 100 may include terrestrial aspects, such as ground-based network entities (e.g., the base station 104a and/or access point 104c), and/or non-terrestrial aspects, such as a spaceborne platform and/or an aerial platform, which may include network entities on-board (e.g., one or more base stations) capable of communicating with other network elements (e.g., terrestrial base stations) and/or user equipment.

The base station 104a may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and/or others. The base station 104a may provide communications coverage for a respective geographic coverage area, which may sometimes be referred to as a cell, and which may overlap in some cases (e.g., a small cell may have a coverage area that overlaps the coverage area of a macro cell). A base station may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

The first wireless device 102 and/or the UE 104d may generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. A UE may also be referred to more generally as a mobile device, a wireless device, a wireless communications device, a wireless station (STA), a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and other terms.

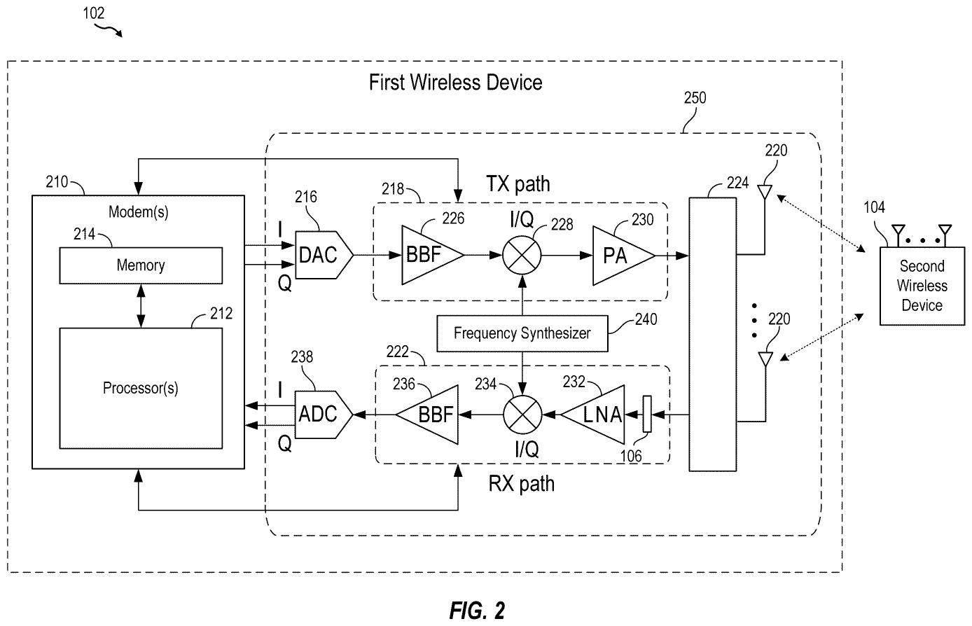

FIG. 2 illustrates example components of the first wireless device 102, which may be used to communicate with any of the second wireless devices 104.

The first wireless device 102 may be, or may include, a chip, system on chip (SoC), system in package (SiP), chipset, package, device that includes one or more modems 210 (hereinafter “the modem 210”). In some cases, the modem 210 may include, for example, any of a WWAN modem (e.g., a modem configured to communicate via E-UTRA, 5G NR, and/or any future WWAN communications standards), a WLAN modem (e.g., a modem configured to communicate via IEEE 802.11 standards), a Bluetooth modem, a NTN modem, etc. In certain aspects, the first wireless device 102 also includes one or more RF transceivers (hereinafter “the RF transceiver 250”). In some cases, the RF transceiver 250 may be referred to as an RF front end (RFFE). In some aspects, the modem 210 further includes one or more processors, processing blocks or processing elements (hereinafter “the processor 212”) and one or more memory blocks or elements (hereinafter “the memory 214”). In certain aspects, the processor 212 and/or the memory 214 are implemented external or otherwise separate from the modem 210.

In certain aspects, the processor 212 may process any of certain protocol stack layers associated with a radio access technology (RAT). For example, the processor 212 may process any of an application layer, packet layer, WLAN protocol stack layers (e.g., a link or a medium access control (MAC) layer), and/or WWAN protocol stack layers (e.g., a radio resource control (RRC) layer, a packet data convergence protocol (PDCP) layer, a radio link control (RLC) layer, and a MAC layer).

The modem 210 may generally be configured to implement a physical (PHY) layer. For example, the modem 210 may be configured to modulate packets and to output the modulated packets to the RF transceiver 250 for transmission over a wireless medium. The modem 210 is similarly configured to obtain modulated packets received by the RF transceiver 250 and to demodulate the packets to provide demodulated packets. In addition to a modulator and a demodulator, the modem 210 may further include digital signal processing (DSP) circuitry, automatic gain control (AGC), a coder, a decoder, a multiplexer, and/or a demultiplexer (not shown).

As an example, while in a transmission mode, the modem 210 may obtain data from a data source, such as an application processor. The data may be provided to a coder, which encodes the data to provide encoded bits. The encoded bits may be mapped to points in a modulation constellation (e.g., using a selected modulation and coding scheme) to provide modulated symbols. The modulated symbols may be mapped, for example, to spatial stream(s) or space-time streams. The modulated symbols may be multiplexed, transformed via an inverse fast Fourier transform (IFFT) block, and subsequently provided to DSP circuitry for transmit windowing and filtering. The digital signals may be provided to a digital-to-analog converter (DAC) 216. In certain aspects involving beamforming, the modulated symbols in the respective spatial streams may be precoded via a steering matrix prior to provision to the IFFT block.

The modem 210 may be coupled to the RF transceiver 250 by a transmit (TX) path 218 (also known as a transmit chain) for transmitting signals via one or more antennas 220 (hereinafter “the antennas 220”) and a receive (RX) path 222 (also known as a receive chain) for receiving signals via the antennas 220. When the TX path 218 and the RX path 222 share the antennas 220, the paths may be coupled to the antennas 220 via an interface 224, which may include any of various suitable RF devices, such as a balun, a transformer, an antenna tuner, a switch, a duplexer, a diplexer, a multiplexer, an RF coupler, or the like. As an example, the modem 210 may output digital in-phase (I) and/or quadrature (Q) baseband signals representative of the respective symbols to the DAC 216. In some examples, all or most of the elements illustrated as being included in the RF transceiver 250 are implemented in a single chip or die. For example, in some configurations, all of the elements of the RF transceiver except the antennas 220 are implemented on a single chip. In some other configurations, the interface 224 and the PA 230 or a portion thereof is also omitted from the single chip.

Receiving I or Q baseband analog signals from the DAC 216, the TX path 218 may include a baseband filter (BBF) 226, a mixer 228 (which may include one or several mixers), and a power amplifier (PA) 230. The BBF 226 filters the baseband signals received from the DAC 216, and the mixer 228 mixes the filtered baseband signals with a transmit local oscillator (LO) signal to convert the baseband signal to a different frequency (e.g., upconvert from a baseband frequency to a radio frequency). In some aspects, the frequency conversion process produces the sum and difference frequencies between the LO frequency and the frequencies of the baseband signal. The sum and difference frequencies are referred to as the beat frequencies. Some beat frequencies are in the RF range, such that the signals output by the mixer 228 are typically RF signals, which may be amplified by the PA 230 before transmission by the antennas 220. The antennas 220 may emit RF signals, which may be received at the second wireless device 104. While one mixer 228 is illustrated, several mixers may be used to upconvert the filtered baseband signals to one or more intermediate frequencies and to thereafter upconvert the intermediate frequency signals to a frequency for transmission.

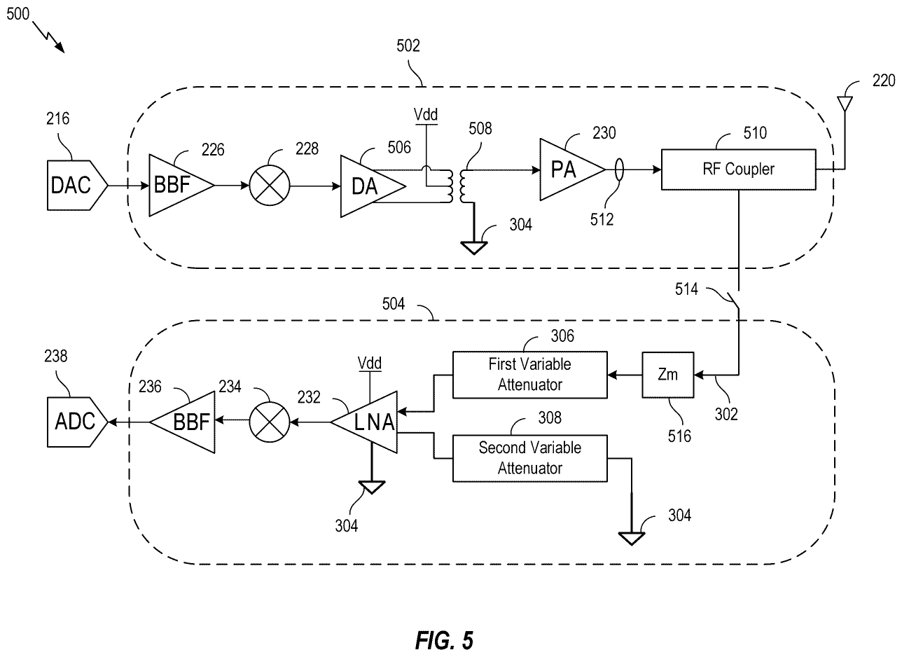

The RX path 222 may include a low noise amplifier (LNA) 232, a mixer 234 (which may include one or several mixers), and a baseband filter (BBF) 236. RF signals received via the antennas 220 (e.g., from the second wireless device 104) may be amplified by the LNA 232, and the mixer 234 mixes the amplified RF signals with a receive local oscillator (LO) signal to convert the RF signal to a baseband frequency (e.g., downconvert the RF signal to the baseband frequency). The baseband signals output by the mixer 234 may be filtered by the BBF 236 before being converted by an analog-to-digital converter (ADC) 238 to digital I or Q signals for digital signal processing. The modem 210 may receive the digital I or Q signals and further process the digital signals, for example, demodulating the digital signals into information. In certain cases, the RX path 222 may also include the isolation circuitry 106, which may enable crosstalk isolation or suppression, for example, between the TX path 218 and the RX path 222. In certain aspects, the RX path 222 may be an example of a feedback receive path, for example, as further described herein with respect to FIG. 5. As an example, the isolation circuitry 106 may be coupled between the LNA 242 and the interface 224. In some examples, when the RX path 222 is configured as a feedback receive path, it is incapable of or not configured to receive signals from the antennas 220.

Certain transceivers may employ frequency synthesizers with a voltage-controlled oscillator (VCO) to generate a stable, tunable LO frequency with a particular tuning range. Thus, the transmit LO frequency may be produced by a frequency synthesizer 240, which may be buffered or amplified by an amplifier (not shown) before being mixed with the baseband signals in the mixer 228. Similarly, the receive LO frequency may be produced by the frequency synthesizer 240, which may be buffered or amplified by an amplifier (not shown) before being mixed with the RF signals in the mixer 234. Separate frequency synthesizers may be used for the TX path 218 and the RX path 222.

While in a reception mode, the modem 210 may obtain digitally converted signals via the ADC 238 and RX path 222. As an example, in the modem 210, digital signals may be provided to the DSP circuitry, which is configured to acquire a received signal, for example, by detecting the presence of the signal and estimating the initial timing and frequency offsets. The DSP circuitry is further configured to digitally condition the digital signals, for example, using channel (narrowband) filtering, analog impairment conditioning (such as correcting for I/Q imbalance), and applying digital gain to ultimately obtain a narrowband signal. The output of the DSP circuitry may be fed to the AGC, which is configured to use information extracted from the digital signals, for example, in one or more received training fields, to determine an appropriate gain. The output of the DSP circuitry also may be coupled with the demodulator, which is configured to extract modulated symbols from the signal and, for example, compute the logarithm likelihood ratios (LLRs) for each bit position of each subcarrier in each spatial stream. The demodulator may be coupled with the decoder, which may be configured to process the LLRs to provide decoded bits. The decoded bits from all of the spatial streams may be fed to the demultiplexer for demultiplexing. The demultiplexed bits may be descrambled and provided to a medium access control layer (e.g., the processor 212) for processing, evaluation, or interpretation.

The modem 210 and/or processor 212 may control the transmission of signals via the TX path 218 and/or reception of signals via the RX path 222. In some aspects, the modem 210 and/or processor 212 may be configured to perform various operations, such as those associated with any of the methods described herein. In certain cases, the modem 210 and/or processor 212 may be configured to monitor the performance of the TX path 218 and/or perform calibration of the TX path 218, for example, via RF signaling output by the TX path 218 and fed back to the modem 210 and/or processor 212 via the RX path 222, as further described herein with respect to FIG. 5. The modem 210 and/or processor 212 may include a microcontroller, a microprocessor, an application processor, a baseband processor, a MAC processor, an artificial intelligence (AI) processor, a digital signal processor (DSP), an application specific integrated circuit (ASIC), a field programmable gate array (FPGA) or other programmable logic device (PLD), discrete gate or transistor logic, discrete hardware components, or any combination thereof. The memory 214 may store data and program codes (e.g., processor-readable instructions) for performing wireless communications as described herein. In some cases, the memory 214 may be external to the modem 210 and/or processor 212 and/or incorporated therein (as illustrated with the memory 214 or being incorporated with the processor 212).

FIG. 2 shows an example transceiver design. It will be appreciated that other transceiver designs or architectures may be applied in connection with aspects of the present disclosure. For example, while examples discussed herein utilize I and Q signals (e.g., quadrature modulation), those of skill in the art will understand that components of the transceiver may be configured to utilize any other suitable modulation, such as polar modulation. As another example, circuit blocks may be arranged differently from the configuration shown in FIG. 2, and/or other circuit blocks not shown in FIG. 2 may be implemented in addition to or instead of the blocks depicted.

### Example Feedback Receive Path Isolation Circuitry

Aspects of the present disclosure provide certain feedback receive path isolation circuitry that may enable crosstalk isolation or suppression, for example, between a transmit path and feedback receive path of a transceiver.

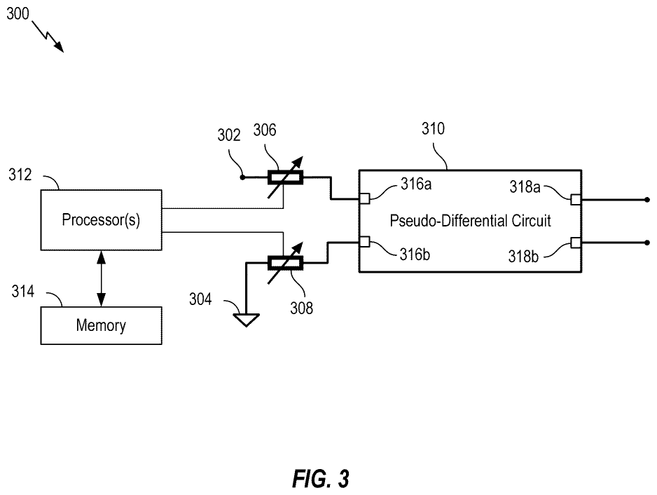

FIG. 3 depicts an example architecture of feedback receive path isolation circuitry 300. In certain aspects, the feedback receive path isolation circuitry 300 may be part of a feedback receive path (such as an input stage of the feedback receive path) as further described herein with respect to FIG. 5. In certain aspects, the feedback receive path isolation circuity 300 may be part of a transceiver, such as the RF transceiver 250 of FIG. 2. The feedback receive path isolation circuitry 300 may be an example of the isolation circuitry 106 of FIGS. 1 and 2.

The feedback receive path isolation circuitry 300 may include an input node 302, a reference node 304, a first variable attenuator 306, and a second variable attenuator 308. The feedback receive path isolation circuitry 300 may be coupled to a pseudo-differential circuit 310. In certain cases, the feedback receive path isolation circuitry 300 may include the pseudo-differential circuit 310. In certain cases, the feedback receive path isolation circuitry 300 may further include or be coupled to one or more processors (hereinafter “the processor 312”) and one or more memories (hereinafter “the memory 314”) coupled with or to the processor 312. The processor 312 may be an example of the modem 210 and/or the processor 212 of FIG. 2, and the memory 314 may be an example of the memory 214 of FIG. 2. The memory 314 may store data and program codes (e.g., processor-readable instructions) for controlling the attenuation of the first variable attenuator 306 and/or the second variable attenuator 308 as further described herein

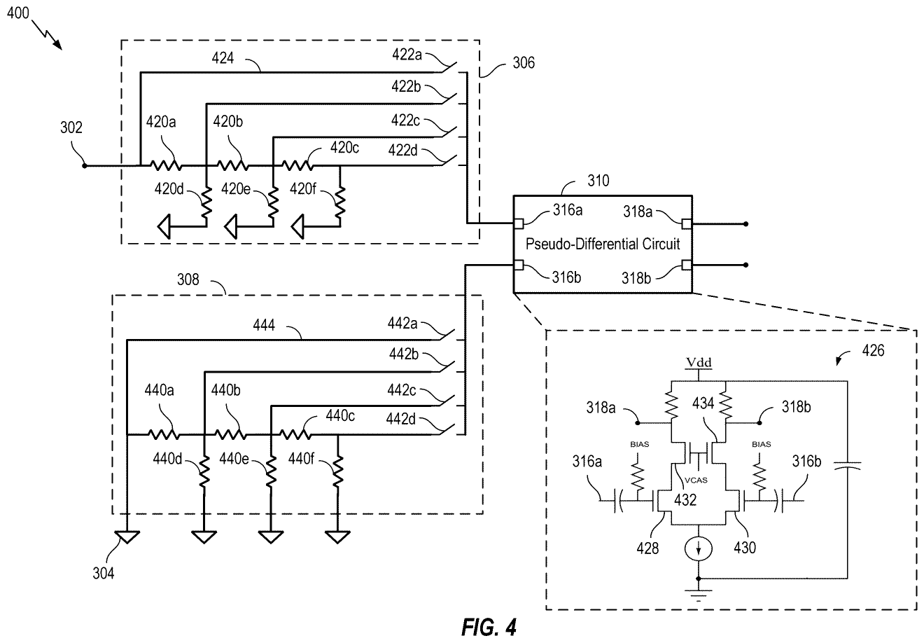

The pseudo-differential circuit 310 may be or include a differential circuit having differential input ports 316a, 316b and differential output ports 318a, 318b, where one of the differential input ports (e.g., the second input port 316b) is coupled to the reference node 304, for example, via the second variable attenuator 308. Thus, the pseudo-differential circuit 310 may be or include a circuit effectively having a single-ended input port and differential output ports. In certain cases, the pseudo-differential circuit 310 may include an amplifier circuit, such as a low-noise amplifier having differential output ports, for example, as further described herein with respect to FIG. 4 and FIG. 5. As an example, the pseudo-differential circuit 310 may feed an amplified signal, via the differential output ports 318a, 318b, to certain circuitry in a receive path, such as one or more mixers and/or a baseband filter, for example, as described herein with respect to FIG. 2. In other examples, the pseudo-differential circuit 310 is configured as a mixer (and the LNA 232 is omitted) and may feed a downconverted signal, via the differential output ports 318a, 318b, to certain circuitry in a receive path, such as a baseband filter, for example, as described herein with respect to FIG. 2

Each of the first variable attenuator 306 and the second variable attenuator 308 may be or include a digital potentiometer, for example, as further described herein with respect to FIG. 4. As an example, the digital potentiometer may include an array of resistors and a plurality of switches, where each switch is coupled to a different node of the resistor array. Each of the first variable attenuator 306 and the second variable attenuator 308 may be configured to adjust a resistance of the respective attenuator, for example, based on a control signal, such as from the processor 312. In certain cases, each of the first variable attenuator 306 and the second variable attenuator 308 may be configured to apply a range of attenuations, for example, 0 dB to −32 dB. Each of the first variable attenuator 306 and the second variable attenuator 308 may include a bypass path that may effectively enable 0 dB of attenuation.

The input node 302 may be or include a single-ended signal path coupled between the first variable attenuator 306 and another circuit (not shown), such as the TX path 218 of FIG. 2, for example, as further described herein with respect to FIG. 5. The input node 302 may be part of the input stage of the feedback receive path, which may include at least the input ports of an amplifier, such as a low noise amplifier. The input stage may receive a signal from the other circuit and process the signal (e.g., amplify and/or buffer the signal). In certain aspects, an impedance matching circuit 516 may be coupled between the input node 302 and the first variable attenuator 306, for example, as further described herein with respect to FIG. 5. The reference node 304 may be or include a reference potential node or circuit ground, such as a common ground associated with an RF transceiver circuit. As an example, the reference node may be coupled to a printed circuit board (PCB) ground or a circuit package ground.

The processor 312 may be coupled to the first variable attenuator 306 and/or the second variable attenuator 308 to control the resistance of the respective attenuator. The processor 312 may control the signal attenuation applied by or at the first variable attenuator 306 and/or the second variable attenuator 308. The processor 312 may be configured to adjust a first resistance of the first variable attenuator 306 and a second resistance of the second variable attenuator 308 based at least in part on a gain level associated with a signal fed to the input node. For example, the processor 312 may feed, to each of the first variable attenuator 306 and the second variable attenuator 308, a specific control signal that indicates a resistance setting for the respective attenuator, for example, depending on the gain level associated with the signal fed to the input node.

In certain aspects, the signal fed to the input node 302 may be associated with a specific gain level among multiple gain levels, for example, supported by a transmit path (such as the TX path 218 of FIG. 2), as further described herein with respect to FIG. 5. As an example, when the signal fed to the input node 302 is at a first gain level (e.g., a corresponding high power), the processor 312 may set the resistance of the first variable attenuator 306 to a high attenuation (e.g., −30 dB of attenuation). The first variable attenuator 306 may attenuate the signal to be within an input voltage range of the pseudo-differential circuit 310 (such as a peak common-mode voltage). When the signal fed to the input node 302 is at a second gain level (e.g., a corresponding low power), the processor 312 may set the resistance of the first variable attenuator 306 to a low attenuation or effectively no attenuation (e.g., 0 dB of attenuation). As an example, the first variable attenuator 306 may allow the signal to be conducted through a bypass path of the first variable attenuator 306, as further described herein with respect to FIG. 4. At the first gain level, the signal may have a higher power than the signal at the second gain level. Accordingly, the attenuation applied to the signal at the first gain level may be different from the other attenuation applied to the signal at the second gain level.

The second variable attenuator 308 may be used to balance the resistance of the first variable attenuator 306 to suppress crosstalk from another circuit, such as the TX path 218, and/or isolate the pseudo-differential circuit 310 from the crosstalk. The resistance of the second variable attenuator 308 may be set to effectively suppress the crosstalk that is carried through a common power supply node (e.g., Vdd) and/or the reference node 304 (e.g., the circuit ground). The second variable attenuator 308 may enable crosstalk suppression and/or isolation over a wide bandwidth of RF frequencies, such as 600 MHz to 7.2 GHz. The bandwidth of crosstalk suppression and/or isolation may match the transmission bandwidth supported by a transmit path, such as the TX path 218. The wide bandwidth of crosstalk suppression and/or isolation may be enabled due to the attenuation being implemented via or applied via one or more resistors, for example, without frequency tuning of reactance components, such as an inductor, transformer, and/or capacitor.

In certain cases, the processor 312 may adjust the resistance of the second variable attenuator 308 to match the resistance (or attenuation) of the first variable attenuator 306. As an example, when a specific attenuation is applied at the first variable attenuator 306, the same attenuation may also be applied at the second variable attenuator 308, such as an attenuation of 30 dB. In certain aspects, the attenuation applied at the first variable attenuator 306 and the second variable attenuator 308 may be within a threshold difference of each other, for example, due to variations (or mismatches) in resistance specifications or values associated with the first variable attenuator 306 and the second variable attenuator 308. As another example, the processor 312 may be configured to adjust the first resistance of the first variable attenuator 306 to a first resistance value, and adjust the second resistance of the second variable attenuator 308 to a second resistance value within a threshold difference of the first resistance. The threshold difference may be or include ±0.1%, 0.5%, 1%, 5%, or the like, with respect to the first resistance.

FIG. 4 depicts another example architecture of feedback receive path isolation circuitry 400. In this example, each of the first variable attenuator 306 and the second variable attenuator 308 may be or include a digital potentiometer. The first variable attenuator 306 may include an array of resistors (e.g., including a first resistor 420a, a second resistor 420b, a third resistor 420c, a fourth resistor 420d, a fifth resistor 420e, and a sixth resistor 420f) and a plurality of switches (e.g., including a first switch 422a, a second switch 422b, a third switch 422c, and a fourth switch 422d). The resistors 420a-c may be arranged in series with each other. The resistors 420a-c may have the same resistance value or various resistance values. The resistors 420d-f may be coupled between the reference node 304 and at least one of the resistors 420a-c. The resistors 420d-f may serve as biasing resistors to maintain a certain level of current and/or voltage at the first input port 316a. Each of the switches 422a-d may be or include one or more transistors, for example, coupled to the processor 312 of FIG. 3.

Each of the switches 422a-d may be coupled to a specific node of the array of resistors 420a-c. As an example, the first switch 422a may include a terminal coupled between the input node 302 and the first resistor 420a to allow for a bypass path 424. The second switch 422b may include a terminal coupled between the first resistor 420a and the second resistor 420b. The third switch 422c may include a terminal coupled between the second resistor 420b and the third resistor 420c. The fourth switch 422d may be coupled between the third resistor 420c and the first input port 316a of the pseudo-differential circuit 310. Each of the switches 422a-d may include a terminal coupled to the first input port 316a of the pseudo-differential circuit 310. Note that additional or alternative resistors and/or switches may be included in the first variable attenuator 306 to enable additional or alternative levels of attenuation.

The same digital potentiometer architecture described herein with respect to the first variable attenuator 306 may be applied to the second variable attenuator 308. For example, the second variable attenuator 308 may include an array of resistors 440a-f, a plurality of switches 442a-d, and a bypass path 444, each of which may be arranged as described herein with respect to the corresponding components of the first variable attenuator 306.

In certain cases, the second variable attenuator 308 may replicate the first variable attenuator 306. At least one resistor of the first variable attenuator 306 (for example, the first resistor 420a) may generally have the same physical characteristic(s) as at least one resistor of the second variable attenuator 308 (for example, the first resistor 440a). As an example, the first resistor 420a of the first variable attenuator 306 may have the same physical dimensions as the first resistor 440a of the second variable attenuator 308 for example, in terms of an aspect ratio, width, length, height, and/or the like. The first resistor 420a of the first variable attenuator 306 and the first resistor 440a of the second variable attenuator 308 may be formed of the same material, such as a semiconductor material (e.g., diffusion region, n-well region, a polysilicon layer, or the like), a conductive material, and/or the like. Thus, the same physical characteristic(s) may result in the first resistor 420a of the first variable attenuator 306 and the first resistor 440a of the second variable attenuator 308 having the same resistance or resistances within a threshold difference of each other. The array of resistors 420a-c of the first variable attenuator 306 and the other array of resistors 440a-c of the second variable attenuator 308 may be symmetrically arranged with respect to the pseudo-differential circuit 310. In some cases, the second variable attenuator 308 may be referred to as a dummy attenuator.

In certain aspects, the pseudo-differential circuit 310 may include an amplifier circuit 426, such as a differential amplifier. In certain cases, the amplifier circuit 426 may include a transistor amplifier topology, such as a common-source amplifier, a common-gate amplifier, or the like. As an example, the amplifier circuit 426 may include a plurality of transistors including a first transistor 428, a second transistor 430, a third transistor 432, and a fourth transistor 434. With respect to an example of common-source stage, the first input port 316a may be coupled to a gate of the first transistor 428, and the second input port 316b may be coupled to a gate of the second transistor 430. In certain aspects, the amplifier circuit 426 may include a cascode topology, such as a common-gate cascode stage. As part of a cascode topology, a first output port 318a of the differential output ports 318a, 318b may be coupled to a drain of the third transistor 432, and a second output port 318b of the differential output ports 318a, 318b may be coupled to a drain of the fourth transistor 434. In certain cases, the gates of the third transistor 432 and the fourth transistor 434 may be coupled to each other to enable voltage-controlled amplification at the cascode stage. In certain cases, the amplifier circuit 426 may include a plurality of amplifiers coupled in parallel with each other, where the plurality of amplifiers include transconductance-sliced (gₘ-sliced) amplifiers. A variable attenuator may be respectively coupled to each input of each of the plurality of amplifiers, or a common variable attenuator may be coupled to inputs of multiple (e.g., all) amplifiers of the plurality of amplifiers. In certain cases, the amplifier circuit 426 may include a common-mode bias applied to the gate of the first transistor 428 and the gate of the second transistor 430, for example, via a common-mode resistors. In certain cases, a decoupling capacitor may be coupled between a power supply node (Vdd) and the circuit ground.

Note that the transistor amplifier topology of the amplifier circuit 426 depicted in FIG. 4 is an example pseudo-differential architecture, and other suitable circuit architectures may be used for the pseudo-differential circuit 310.

FIG. 5 depicts an example transceiver 500 including a transmit path 502 coupled to a feedback receive path 504 that includes isolation circuitry, for example, as described herein with respect to FIGS. 3 and 4. In this example, the transceiver 500 may include the DAC 216, the ADC 238, and the antennas 220 of FIG. 2. The DAC 216 may feed an analog baseband signal (which may include one or more in-phase signals and one or more quadrature signals), to the transmit path 502, for RF signal processing, such as filtering, upconversion, amplification, and/or transmission. The transmit path 502 may include the components of the TX path 218 of FIG. 2, such as the BBF 226, the mixer 228, and the PA 230.

In certain cases, the transmit path 502 may further include a driver amplifier 506 (DA), a balun 508, and an RF coupler 510. The DA 506 may be part of a transceiver circuit or package, and the PA 230 may be part of an amplifier circuit or package arranged proximate to the antennas 220. Thus, the DA 506 may be part of a different circuit or package than the PA 230. In certain cases, the DA 506 and PA 230 may be part of the same circuit or package. The mixer 228 may feed an upconverted RF signal to the DA 506, and the DA 506 may amplify the RF signal to overcome and/or compensate for certain power loss(es) encountered by the RF signal between the DA 506 and the PA 230, for example, due to transmission line impedance(s).

The balun 508 may convert a differential signal output by the DA 506 to a common-mode signal, which is then fed to the PA 230. The balun 508 may include a center-tap coupled to a power supply node (e.g., Vdd), and the balun 508 may include a secondary winding coupled to the reference node 304 (e.g., a circuit ground). The PA 230 may output the amplified RF signal to the antennas 220 for transmission. The RF coupler 510 may be coupled between the PA 230 and the antennas 220. The RF coupler 510 may be an example of the interface 224 of FIG. 2.

The feedback receive path 504 may include circuitry that enables performance monitoring and/or calibration of the transmit path 502. As an example, the feedback receive path 504 may be configured to convert the RF signal, which is output by the transmit path 502, to a baseband signal for digital signal processing, such as performance monitoring and/or calibration, as further described herein. The feedback receive path 504 may be coupled to the transmit path 502 via the RF coupler 510. For example, the RF coupler 510 may be coupled to the input node 302 of the feedback receive path 504. The PA 230 may include an output port 512 coupled to the input node 302 of the feedback receive path 504 via the RF coupler 510. The input node 302 may include a single-ended signal path coupled between the output port 512 of the PA 230 (via the RF coupler 510) and the first variable attenuator 306. The RF coupler 510 may allow the amplified RF signal output by or at the PA 230 to be fed to the feedback receive path 504 (and the amplified RF signal may also be fed to the antennas 220). In certain cases, a switch 514 may be coupled between the RF coupler 510 and the input node 302 of the feedback receive path, such that the RF coupler 510 may be selectively coupled to the input node 302. The switch may be an example of a plurality of switches that enable the feedback receive path to be selectively coupled to the output ports of multiple PAs.

In certain cases, the feedback receive path 504 may enable performance monitoring of the transmit path 502, for example, in terms of output power, amplitude error, phase error, frequency error, error vector magnitude (EVM), adjacent channel leakage, spectral mask, and/or the like. In certain cases, the feedback receive path 504 may enable calibration of the transmit path 502, such as calibration of certain distortion compensation technique(s) associated with the transmit path. The distortion compensation techniques may include, for example, digital pre-distortion, residual sideband compensation, nonlinearity compensation, and/or the like.

The feedback receive path 504 may include one or more amplifiers, one or more mixers, and one or more filters. For example, the feedback receive path may include the components of the RX path of FIG. 2, such as the LNA 232, the mixer 234, and the BBF 236. The mixer 234 may be coupled to the output(s) of the LNA 242 (e.g., the differential output ports 318a); and the BBF 236 may be coupled to the output(s) of the mixer 234. The LNA 232 may feed an amplified signal to the mixer 234 based on the signal fed to the feedback receive path 504. The mixer 234 may feed a downconverted signal to the BBF 236 based on the amplified signal. Then, the BBF 236 may feed a filtered signal to the ADC 238 for quantization and digital signal processing, for example, at least in part by a modem (e.g., the modem 210 of FIG. 2) and/or one or more processors (e.g., the processor 212). The modem may monitor the performance of the transmit path and/or perform calibration of the transmit path 502.

The LNA 232 may be an example of a pseudo-differential circuit 310, for example, as described herein with respect to FIGS. 3 and 4. In certain cases, the LNA 232 may be coupled to the same power supply node (e.g., Vdd) and the reference node 304 as the transmit path 502. Thus, certain crosstalk from the transmit path 502 may be conductively coupled to the feedback receive path (for example, at the LNA 232) via the reference node 304 and/or the power supply node (e.g., Vdd). Note that alternative or additional source(s) of crosstalk that affect the signal quality of the feedback signal carried through the feedback receive path 504 may be part of the transmit path 502 and/or other circuitry.

The feedback receive path 504 may further include certain isolation circuitry, such as the first variable attenuator 306 and the second variable attenuator 308 as described herein with respect to FIG. 3 and/or FIG. 4. In certain cases, the first variable attenuator 306 and the second variable attenuator 308 may be integrated with or included in the LNA 232. The isolation circuitry may isolate the feedback receive path 504 from (or suppress) crosstalk conducted via the reference node 304 and/or the power supply node (e.g., Vdd). The second variable attenuator 308 may be coupled to the reference node 304 and a differential input port of the LNA 232, for example, as described herein with respect to FIG. 4. The resistance of the second variable attenuator 308 may be set to suppress crosstalk from the transmit path 502 and/or isolate the feedback receive path 504 from crosstalk.

In certain aspects, an impedance matching circuit 516 may be coupled between the first variable attenuator 306 and the input node 302. The impedance matching circuit 516 may include one or more reactive component(s), such as one or more (variable or tunable) capacitors and/or one or more inductors. The impedance matching circuit 516 may be configured to provide a variable input impedance of the feedback receive path 504. The impedance of the impedance matching circuit 516 may be set to match the output impedance of the transmit path 502, for example, as exhibited at the RF coupler 510. In certain cases, the first variable attenuator 306 may be part of or included in the impedance matching circuit 516. For example, the first variable attenuator 306 may be a resistive component of the impedance matching circuit 516. In some cases, the first variable attenuator 306 may be referred to as a matching attenuator. In certain aspects, the impedance matching circuit 516, the isolation circuitry, and the LNA 232 may be part of an input stage of the feedback receive path 504.

In certain aspects, the transmit path 504 may support various levels of gain to output the RF signal at different transmit power levels. For example, the transmit path 504 may be operated at a first gain level (or gain state) to output the RF signal at a first transmit power level, and the transmit path 504 may be operated at a second gain level to output the RF signal at a second transmit power level higher than the first transmit power level. Thus, the signal fed to the feedback receive path 504 via the RF coupler 510 may be at a specific transmit power level, associated with a gain level of the transmit path 502, among various transmit power levels. However, at certain transmit power level(s), the signal fed to the feedback receive path 504 may overload the LNA 232 (for example, in terms of the peak common-mode input voltage supported by the LNA 232). In order to prevent the LNA 232 (and/or other components in the feedback receive path 504) from being overloaded, the first variable attenuator 306 may be controlled to attenuate the signal fed to the feedback receive path 504. For example, the first variable attenuator 306 may have a resistance set to a value that attenuates the signal to be within the input voltage range of the pseudo-differential circuit 310 (e.g., the peak common-mode voltage of the LNA 232) or other circuit component in the feedback receive path 504. In certain cases, the second variable attenuator 308 may have a resistance set to match the resistance of the first variable attenuator 306, for example, as described herein.

Thus, the first variable attenuator 306 and the second variable attenuator 308 may enable improved signal quality across a wide frequency bandwidth using single-ended and/or passive circuitry, such as the resistor arrays described herein with respect to FIG. 4. The isolation circuitry of the feedback receive path 504 may enable improved signal quality without impacting power consumption, circuit complexity, and/or frequency bandwidth specifications. Accordingly, the isolation circuitry may enable reliable performance monitoring and/or calibration associated with the transmit path 502.

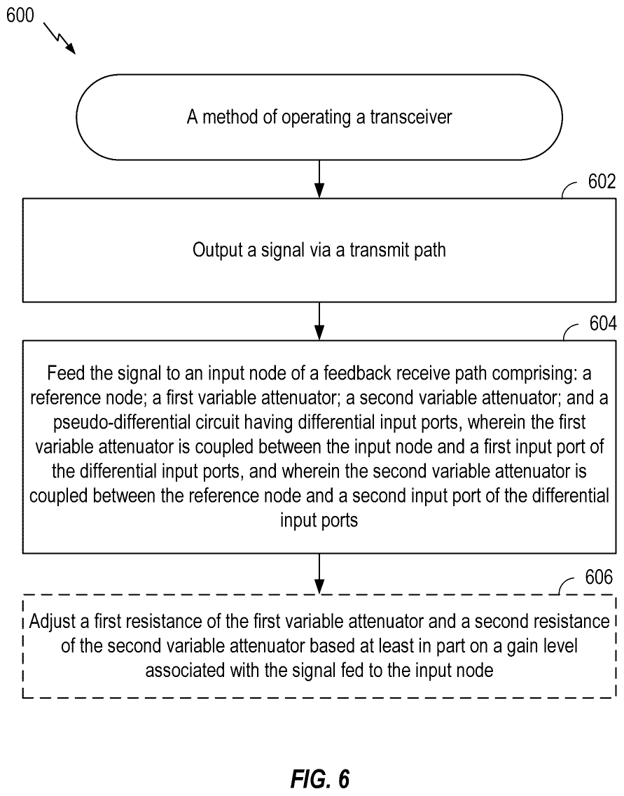

FIG. 6 depicts example operations 600 for operating a transceiver. In certain aspects, the operations 600 may be performed by certain RF circuitry, such as the circuitry of FIG. 3, the circuitry of FIG. 4, and/or the transceiver of FIG. 5. In certain aspects, the operations 600 may be performed, for example, by a wireless device (e.g., the first wireless device 102 in the wireless communications system 100). The operations 600 may be implemented as software components that are executed and run on one or more processors (e.g., the modem 210 and/or the processor 212 of FIG. 2). Further, the transmission and/or reception of signals by the wireless device in the operations 600 may be enabled, for example, by one or more antennas (e.g., the antennas 220 of FIG. 2). In certain aspects, the transmission and/or reception of signals by the wireless device may be implemented via a bus interface of one or more processors (e.g., the modem 210 and/or the processor 212 of FIG. 2) obtaining and/or outputting signals for reception or transmission. Note that any operations illustrated with dashed lines may indicate that that operation may be optional or an alternative.

The operations 600 may optionally begin, at block 602, where the transceiver may output a signal via a transmit path (e.g., the transmit path 218, 502 of FIG. 2 and/or FIG. 5), for example, as described herein with respect to FIGS. 3-5. In certain aspects, outputting the signal via the transmit path comprises outputting the signal via an amplifier of the transmit path, wherein the amplifier (e.g., a power amplifier) includes an output port coupled to the input node of the feedback receive path.

At block 604, the transceiver may feed the signal to an input node of a feedback receive path (e.g., the feedback receive path 504 of FIG. 5) comprising: a reference node; a first variable attenuator; a second variable attenuator; and a pseudo-differential circuit having differential input ports, for example, as described herein with respect to FIGS. 3-5. The first variable attenuator may be coupled between the input node and a first input port of the differential input ports. The second variable attenuator may be coupled between the reference node and a second input port of the differential input ports. In certain aspects, the pseudo-differential circuit comprises an amplifier circuit. In certain aspects, the pseudo-differential circuit comprises differential output ports. In certain aspects, the pseudo-differential circuit comprises a mixer circuit.

At block 606, the transceiver may (optionally) adjust a first resistance of the first variable attenuator and a second resistance of the second variable attenuator based at least in part on a gain level associated with the signal fed to the input node, for example, as described herein with respect to FIGS. 3-5. In certain aspects, adjusting the first resistance and the second resistance comprises: adjusting the first resistance of the first variable attenuator to a first resistance value; and adjusting the second resistance of the second variable attenuator to a second resistance value within a threshold difference of the first resistance (e.g., ±0.1%, 0.5%, 1%, 5%).

In certain aspects, feeding the signal to the input node comprises feeding the signal to the input node via a single-ended signal path coupled between the output port and the input node.

In certain aspects, the first variable attenuator comprises a first array of resistors and a first plurality of switches; and the second variable attenuator comprises a second array of resistors and a second plurality of switches. In certain aspects, adjusting the first resistance and the second resistance comprises enabling at least one first resistor of the first array of resistors via at least one first switch of the first plurality of switches; and enabling at least one second resistor of the second array of resistors via at least one second switch of the second plurality of switches. In certain aspects, the first array of resistors and the second array of resistors are symmetrically arranged with respect to the pseudo-differential circuit.

In certain aspects, the operations 600 may further include amplifying the signal via the pseudo-differential circuit, wherein the pseudo-differential circuit comprises an amplifier circuit.

In certain aspects, the operations 600 may further include outputting an amplified signal, via the pseudo-differential circuit, based at least in part on the signal; feeding the amplified signal to one or more mixers of the feedback receive path; and feeding a downconverted signal, via the one or more mixers, to one or more filters of the feedback receive path based at least in part on the amplified signal, for example, as described herein with respect to FIGS. 2 and 5.

Aspects of the present disclosure may be applied to any of various wireless communication devices (such as a UE, wireless station, base station, access point, and/or the like) described herein.

### Example Communications Device

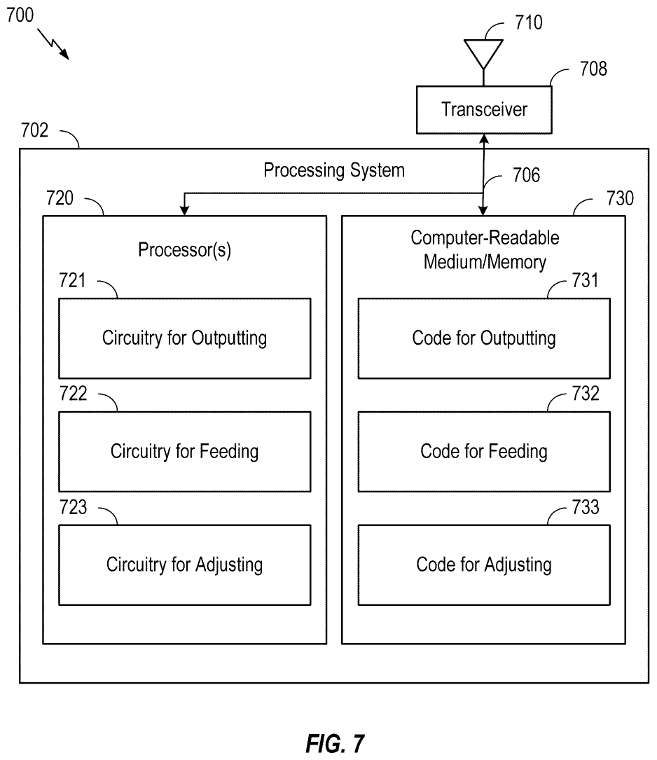

FIG. 7 depicts aspects of an example communications device 700. In some aspects, communications device 700 is a wireless communication device, such as the first wireless device 102 described above with respect to FIGS. 1 and 2.

The communications device 700 includes a processing system 702 coupled to a transceiver 708 (e.g., a transmitter and/or a receiver). The transceiver 708 is configured to transmit and receive signals for the communications device 700 via an antenna 710, such as the various signals described herein. The processing system 702 may be configured to perform processing functions for the communications device 700, including processing signals received and/or to be transmitted by the communications device 700.

The processing system 702 includes one or more processors 720. In various aspects, the one or more processors 720 may be representative of any of the modem 210 and/or the processor 212, as described with respect to FIG. 2. The one or more processors 720 are coupled to a computer-readable medium/memory 730 via a bus 706. In certain aspects, the computer-readable medium/memory 730 is configured to store instructions (e.g., computer-executable code) that when executed by the one or more processors 720, cause the one or more processors 720 to perform the operations 600 described with respect to FIG. 6, or any aspect related to the operations described herein. Note that reference to a processor performing a function of communications device 700 may include one or more processors performing that function of communications device 700. Reference to one or more processors performing multiple functions may include any one of the one or more processors performing any one of the multiple functions.

In the depicted example, computer-readable medium/memory 730 stores code (e.g., executable instructions) for outputting 731, code for feeding 732, code for adjusting 733, or any combination thereof. Processing of the code 731-733 may cause the communications device 700 to perform the operations 600 described with respect to FIG. 6, or any aspect related to operations described herein.

The one or more processors 720 include circuitry configured to implement (e.g., execute) the code stored in the computer-readable medium/memory 730, including circuitry for outputting 721, circuitry for feeding 722, circuitry for adjusting 723, or any combination thereof. Processing with circuitry 721-723 may cause the communications device 700 to perform the operations 600 described with respect to FIG. 6, or any aspect related to operations described herein.

Various components of the communications device 700 may provide means for performing the operations 600 described with respect to FIG. 6, or any aspect related to operations described herein. For example, means for transmitting, sending or outputting for transmission may include the TX path 218 and/or antenna(s) 220 of the first wireless device 102 illustrated in FIG. 2 and/or transceiver 708 and antenna 710 of the communications device 700 in FIG. 7. Means for receiving or obtaining may include the RX path 222 and/or antenna(s) 220 of the first wireless device illustrated in FIG. 2 and/or transceiver 708 and antenna 710 of the communications device 700 in FIG. 7. Means for feeding and/or means for adjusting may include various circuity, such as the RF coupler 510 of FIG. 5, the first variable attenuator 306 of FIGS. 3-5, the second variable attenuator 308 of FIGS. 3-5, the pseudo-differential circuit 310 of FIGS. 3 and 4, the LNA 232 of FIGS. 2 and 5, the mixer 234 of FIGS. 2 and 5, the BBF 236 of FIGS. 2 and 5, and/or one or more processors, such as the modem 210 and/or processor 212 depicted in FIG. 2, the processor 312 of FIG. 3, and/or the processor(s) 720 in FIG. 7.

### Example Aspects

Implementation examples are described in the following numbered clauses:

Aspect 1: A transceiver, comprising: a feedback receive path comprising: an input node; a reference node; a first variable attenuator; a second variable attenuator; and a pseudo-differential circuit having differential input ports, wherein the first variable attenuator is coupled between the input node and a first input port of the differential input ports, and wherein the second variable attenuator is coupled between the reference node and a second input port of the differential input ports.

Aspect 2: The transceiver of Aspect 1, further comprising one or more processors and one or more memories coupled with the one or more processors, the one or more processors configured to adjust a first resistance of the first variable attenuator and a second resistance of the second variable attenuator based at least in part on a gain level associated with a signal fed to the input node.

Aspect 3: The transceiver of Aspect 2, wherein to adjust the first resistance and the second resistance, the one or more processors are configured to: adjust the first resistance of the first variable attenuator to a first resistance value; and adjust the second resistance of the second variable attenuator to a second resistance value within a threshold difference of the first resistance.

Aspect 4: The transceiver according to any of Aspects 1-3, wherein the pseudo-differential circuit comprises an amplifier circuit.

Aspect 5: The transceiver according to any of Aspects 1-4, wherein the pseudo-differential circuit comprises differential output ports.

Aspect 6: The transceiver according to any of Aspects 1-5, further comprising a transmit path coupled to the input node of the feedback receive path.

Aspect 7: The transceiver of Aspect 6, wherein the transmit path comprises a power amplifier having an output port coupled to the input node of the feedback receive path.

Aspect 8: The transceiver of Aspect 7, wherein the input node comprises a single-ended signal path coupled between the first variable attenuator and the output port of the power amplifier.

Aspect 9: The transceiver according to any of Aspects 1-8, wherein: the first variable attenuator comprises a first array of resistors and a first plurality of switches; and the second variable attenuator comprises a second array of resistors and a second plurality of switches.

Aspect 10: The transceiver of Aspect 9, wherein the first array of resistors and the second array of resistors are symmetrically arranged with respect to the pseudo-differential circuit.

Aspect 11: The transceiver according to any of Aspects 1-10, wherein the feedback receive path further comprises: one or more mixers coupled to outputs of the pseudo-differential circuit; and one or more filters coupled to one or more outputs of the one or more mixers.

Aspect 12: A method for operating a transceiver, comprising: outputting a signal via a transmit path; and feeding the signal to an input node of a feedback receive path comprising: a reference node; a first variable attenuator; a second variable attenuator; and a pseudo-differential circuit having differential input ports, wherein the first variable attenuator is coupled between the input node and a first input port of the differential input ports, and wherein the second variable attenuator is coupled between the reference node and a second input port of the differential input ports.

Aspect 13: The method of Aspect 12, further comprising adjusting a first resistance of the first variable attenuator and a second resistance of the second variable attenuator based at least in part on a gain level associated with the signal fed to the input node.

Aspect 14: The method of Aspect 13, wherein adjusting the first resistance and the second resistance comprises: adjusting the first resistance of the first variable attenuator to a first resistance value; and adjusting the second resistance of the second variable attenuator to a second resistance value within a threshold difference of the first resistance.

Aspect 15: The method according to any of Aspects 12-14, further comprising amplifying the signal via the pseudo-differential circuit, wherein the pseudo-differential circuit comprises an amplifier circuit.

Aspect 16: The method according to any of Aspects 12-15, wherein the pseudo-differential circuit comprises differential output ports.

Aspect 17: The method according to any of Aspects 12-16, wherein outputting the signal via the transmit path comprises outputting the signal via a power amplifier of the transmit path, wherein the power amplifier includes an output port coupled to the input node of the feedback receive path.

Aspect 18: The method of Aspect 17, wherein feeding the signal to the input node comprises feeding the signal to the first variable attenuator via a single-ended signal path coupled between the output port and the first variable attenuator.

Aspect 19: The method according to any of Aspects 13-18, wherein adjusting the first resistance and the second resistance comprises enabling at least one first resistor of a first array of resistors via at least one first switch of a first plurality of switches, wherein the first variable attenuator comprises the first array of resistors and the first plurality of switches; and enabling at least one second resistor of a second array of resistors via at least one second switch of a second plurality of switches, wherein the second variable attenuator comprises the second array of resistors and the second plurality of switches.

Aspect 20: The method of Aspect 19, wherein the first array of resistors and the second array of resistors are symmetrically arranged with respect to the pseudo-differential circuit.

Aspect 21: The method according to any of Aspects 12-20, further comprising: outputting an amplified signal, via the pseudo-differential circuit, based at least in part on the signal; feeding the amplified signal to one or more mixers of the feedback receive path; and feeding a downconverted signal, via the one or more mixers, to one or more filters of the feedback receive path based at least in part on the amplified signal.

Aspect 22: An apparatus, comprising: a memory; and one or more processors configured to perform a method in accordance with any of Aspects 1-21.

Aspect 23: An apparatus, comprising means for performing a method in accordance with any of Aspects 1-21.

Aspect 24: A non-transitory computer-readable medium comprising computer-executable instructions that, when executed by one or more processors of a processing system, cause the processing system to perform a method in accordance with any of Aspects 1-21.

Aspect 25: A computer program product embodied on a computer-readable storage medium comprising code for performing a method in accordance with any of Aspects 1-21.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a microcontroller, a microprocessor, a general purpose processor, an artificial intelligence (AI) processor, a digital signal processor (DSP), an ASIC, a field programmable gate array (FPGA) or other programmable logic device (PLD), discrete gate or transistor logic, discrete hardware components, or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), a system in package (SiP), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and or like. Also, “determining” may include receiving (e.g., receiving information), accessing (e.g., accessing data in a memory) or the like. Also, “determining” may include resolving, selecting, choosing, establishing or the like.

As used herein, “coupled to” and “coupled with” generally encompass direct coupling and indirect coupling (e.g., including intermediary coupled aspects) unless stated otherwise. For example, stating that a processor is coupled to a memory allows for a direct coupling or a coupling via an intermediary aspect, such as a bus.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Reference to an element in the singular is not intended to mean only one unless specifically so stated, but rather “one or more.” The subsequent use of a definite article (e.g., “the” or “said”) with an element (e.g., “the processor”) is not intended to invoke a singular meaning (e.g., “only one”) on the element unless otherwise specifically stated. For example, reference to an element (e.g., “a processor,” “a controller,” “a memory,” “a transceiver,” “an antenna,” “the processor,” “the controller,” “the memory,” “the transceiver,” “the antenna,” etc.), unless otherwise specifically stated, should be understood to refer to one or more elements (e.g., “one or more processors,” “one or more controllers,” “one or more memories,” “one or more transceivers,” etc.). The terms “set” and “group” are intended to include one or more elements, and may be used interchangeably with “one or more.” Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions. Unless specifically stated otherwise, the term “some” refers to one or more. All structural and functional equivalents to the elements of the various aspects described throughout this disclosure that are known or later come to be known to those of ordinary skill in the art are intended to be encompassed by the claims. Moreover, nothing disclosed herein is intended to be dedicated to the public regardless of whether such disclosure is explicitly recited in the claims.

1. A transceiver, comprising:
a feedback receive path comprising:
an input node;
a reference node;
a first variable attenuator;
a second variable attenuator; and
a pseudo-differential circuit having differential input ports, wherein the first variable attenuator is coupled between the input node and a first input port of the differential input ports, and wherein the second variable attenuator is coupled between the reference node and a second input port of the differential input ports.

2. The transceiver of claim 1, further comprising one or more processors and one or more memories coupled with the one or more processors, the one or more processors configured to adjust a first resistance of the first variable attenuator and a second resistance of the second variable attenuator based at least in part on a gain level associated with a signal fed to the input node.

3. The transceiver of claim 2, wherein to adjust the first resistance and the second resistance, the one or more processors are configured to:
adjust the first resistance of the first variable attenuator to a first resistance value; and
adjust the second resistance of the second variable attenuator to a second resistance value within a threshold difference of the first resistance.

4. The transceiver of claim 1, wherein the pseudo-differential circuit comprises an amplifier circuit.

5. The transceiver of claim 1, wherein the pseudo-differential circuit comprises differential output ports.

6. The transceiver of claim 1, further comprising a transmit path coupled to the input node of the feedback receive path.

7. The transceiver of claim 6, wherein the transmit path comprises a power amplifier having an output port coupled to the input node of the feedback receive path.

8. The transceiver of claim 7, wherein the input node comprises a single-ended signal path coupled between the first variable attenuator and the output port of the power amplifier.

9. The transceiver of claim 1, wherein:
the first variable attenuator comprises a first array of resistors and a first plurality of switches; and
the second variable attenuator comprises a second array of resistors and a second plurality of switches.

10. The transceiver of claim 9, wherein the first array of resistors and the second array of resistors are symmetrically arranged with respect to the pseudo-differential circuit.

11. The transceiver of claim 1, wherein the feedback receive path further comprises:
one or more mixers coupled to outputs of the pseudo-differential circuit; and
one or more filters coupled to one or more outputs of the one or more mixers.

12. A method for operating a transceiver, comprising:
outputting a signal via a transmit path; and
feeding the signal to an input node of a feedback receive path comprising:
a reference node;
a first variable attenuator;
a second variable attenuator; and
a pseudo-differential circuit having differential input ports, wherein the first variable attenuator is coupled between the input node and a first input port of the differential input ports, and wherein the second variable attenuator is coupled between the reference node and a second input port of the differential input ports.

13. The method of claim 12, further comprising adjusting a first resistance of the first variable attenuator and a second resistance of the second variable attenuator based at least in part on a gain level associated with the signal fed to the input node.

14. The method of claim 13, wherein adjusting the first resistance and the second resistance comprises:
adjusting the first resistance of the first variable attenuator to a first resistance value; and
adjusting the second resistance of the second variable attenuator to a second resistance value within a threshold difference of the first resistance.

15. The method of claim 12, further comprising amplifying the signal via the pseudo-differential circuit, wherein the pseudo-differential circuit comprises an amplifier circuit.

16. The method of claim 12, wherein outputting the signal via the transmit path comprises outputting the signal via a power amplifier of the transmit path, wherein the power amplifier includes an output port coupled to the input node of the feedback receive path.

17. The method of claim 16, wherein feeding the signal to the input node comprises feeding the signal to the first variable attenuator via a single-ended signal path coupled between the output port and the first variable attenuator.

18. The method of claim 13, wherein adjusting the first resistance and the second resistance comprises:
enabling at least one first resistor of a first array of resistors via at least one first switch of a first plurality of switches, wherein the first variable attenuator comprises the first array of resistors and the first plurality of switches; and
enabling at least one second resistor of a second array of resistors via at least one second switch of a second plurality of switches, wherein the second variable attenuator comprises the second array of resistors and the second plurality of switches.

19. The method of claim 18, wherein the first array of resistors and the second array of resistors are symmetrically arranged with respect to the pseudo-differential circuit.

20. The method of claim 12, further comprising:
outputting an amplified signal, via the pseudo-differential circuit, based at least in part on the signal;
feeding the amplified signal to one or more mixers of the feedback receive path; and
feeding a downconverted signal, via the one or more mixers, to one or more filters of the feedback receive path based at least in part on the amplified signal.
